(19) United States
(12) Patent Application Publication
(10) Pub. No.: US 2025/0241149 A1
(43) Pub. Date: Jul. 24, 2025

(54) DISPLAY APPARATUS, METHOD OF MANUFACTURING DISPLAY APPARATUS, AND METHOD OF INSPECTING DEFECTS OF DISPLAY APPARATUS

(71) Applicant: SAMSUNG DISPLAY CO., LTD., Yongin-si (KR)

(72) Inventors: Yujin Sin, Yongin-si (KR); Hyunwook Cho, Yongin-si (KR)

(21) Appl. No.: 18/938,992

(22) Filed: Nov. 6, 2024

(30) Foreign Application Priority Data
Jan. 18, 2024 (KR) 10-2024-0008292

(51) Int. Cl. H10K 59/131; H01L 21/66; H10K 59/12; H10K 59/40; H10K 59/80; H10K 71/00; H10K 71/60

(52) U.S. Cl. CPC H10K 59/131; H01L 22/14; H10K 59/1201; H10K 59/40; H10K 71/60; H10K 71/621; H10K 59/872

(57) ABSTRACT

A display apparatus includes a substrate that includes a display area and a peripheral area outside the display area, a sealing substrate disposed on the substrate, a touch sensor layer disposed on the sealing substrate, a trace line disposed on the sealing substrate in the peripheral area, and an inspection line disposed on the trace line and that overlaps the trace line. The inspection line includes a different material from the trace line.

### CROSS-REFERENCE TO RELATED APPLICATION

This application claims priority under 35 U.S.C. § 119 from Korean Patent Application No. 10-2024-0008292, filed on Jan. 18, 2024 in the Korean Intellectual Property Office, the contents of which are herein incorporated by reference in their entirety.

### TECHNICAL FIELD

One or more embodiments are directed to a display apparatus, a method of manufacturing the display apparatus, and a method of inspecting defects in the display apparatus.

### DISCUSSION OF THE RELATED ART

Among display apparatuses, an organic light-emitting display apparatus has advantages of a wide viewing angle, high contrast, and fast response speed, and thus, an organic light-emitting display apparatus is an exemplary next-generation display apparatus.

In general, an organic light-emitting display apparatus includes a thin-film transistor and an organic light-emitting diode as a light-emitting element over a substrate and operates while the organic light-emitting diode emits light. An organic light-emitting display apparatus is used as a display unit for miniaturized products such as mobile phones and for large-scale products such as televisions.

### SUMMARY

One or more embodiments include a display apparatus, a method of manufacturing the display apparatus, and a method of inspecting defects in the display apparatus. However, such a technical problem is just an example, and the disclosure is not limited thereto.

According to one or more embodiments, a display apparatus includes a substrate that includes a display area and a peripheral area outside the display area, a sealing substrate disposed on the substrate, a touch sensor layer disposed on the sealing substrate, a trace line disposed on the sealing substrate in the peripheral area, and an inspection line disposed on the trace line and that overlaps the trace line. The inspection line includes a different material from the trace line.

The touch sensor layer may include driving electrodes and sensing electrodes, and the trace line may be connected to at least some of the driving electrodes and some of the sensing electrodes.

The inspection line may include a conductive oxide.

Each of the trace line and the inspection line may include a plurality of trace lines and a plurality of inspection lines, respectively, and a number of inspection lines may be equal to a number of trace lines.

The inspection line may completely overlap the trace line.

The trace line may be insulated from the inspection line.

An insulating layer may be interposed between the trace line and the inspection line.

The inspection line may be connected to a terminal part arranged in the peripheral area.

According to one or more embodiments, a method of manufacturing a display apparatus includes forming a substrate that includes a display area and a peripheral area, forming an sealing substrate on the substrate, forming a touch sensor layer on the sealing substrate, forming a trace line on the sealing substrate in the peripheral area, and forming an inspection line on the trace line such that the inspection line overlaps the trace line. The inspection line includes a different material from the trace line.

Forming the inspection line may include forming an insulating layer on the trace line, and forming the inspection line on the insulating layer.

Forming the trace line may include forming a first conductive layer, forming, on the first conductive layer, a first photoresist pattern using a first mask, and etching the first conductive layer using the first photoresist pattern as a mask.

Forming the inspection line may include forming a second conductive layer, forming, on the second conductive layer, a second photoresist pattern using a second mask, and etching the second conductive layer using the second photoresist pattern as a mask.

The second mask may be a same as the first mask.

The inspection line may include a conductive oxide.

Each of the trace line and the inspection line may include a plurality of trace lines and a plurality of inspection lines, respectively, and a number of inspection lines may be equal to a number of trace lines.

Forming the touch sensor layer may include forming driving electrodes and sensing electrodes. The trace line may be connected to at least some of the driving electrodes and the sensing electrodes.

The inspection line may be connected to a terminal part in the peripheral area.

According to one or more embodiments, a method of detecting defects in a display apparatus that includes a touch sensor layer includes determining whether a trace line of the touch sensor layer disposed on a sealing substrate of display apparatus in a peripheral area is defective using an inspection line disposed on the trace line and that overlaps the trace line.

Determining whether the trace line is defective may include measuring a resistance of the inspection line through a terminal part connected to the inspection line, and determining whether the trace line has scratches or short-circuit defects through resistance changes in the inspection line.

The inspection line may include a conductive oxide.

### BRIEF DESCRIPTION OF THE DRAWINGS

FIG. 1 is a schematic plan view of a display apparatus according to an embodiment.

FIG. 2 is a schematic plan view of a display apparatus according to an embodiment.

FIG. 3 is a schematic cross-sectional view of a display apparatus according to an embodiment.

FIG. 4 is a schematic cross-sectional view of a display apparatus according to an embodiment.

FIG. 5 is a schematic circuit diagram of a light-emitting diode of a pixel of a display apparatus and a sub-pixel circuit connected to the light-emitting diode, according to an embodiment.

FIG. 6 is a schematic cross-sectional view of a portion of a display area of a display apparatus according to an embodiment.

FIG. 7 is a plan view of a touch sensor layer of a display apparatus according to an embodiment.

FIG. 8 is a plan view of an inspection line of a display apparatus according to an embodiment.

FIG. 9 is a schematic cross-sectional view of a portion of a peripheral area of a display apparatus according to an embodiment.

FIGS. 10A to 10F are cross-sectional views that illustrate a process of manufacturing a display apparatus according to an embodiment.

FIG. 11 is a flowchart of a method of inspecting defects in a display apparatus, according to an embodiment.

FIG. 12 is a cross-sectional view that illustrates a method of inspecting defects in a display apparatus, according to an embodiment.

### DETAILED DESCRIPTION

Reference will now be made in detail to embodiments, examples of which are illustrated in the accompanying drawings, wherein like reference numerals may refer to like elements throughout.

It will be further understood that, when a layer, region, or element is referred to as being “on” another layer, region, or element, it can be directly or indirectly on the other layer, region, or element.

In the case where a certain embodiment may be implemented differently, a specific process order may be performed in an order different from a described order. For example, two processes successively described may be simultaneously performed substantially and performed in the opposite order.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

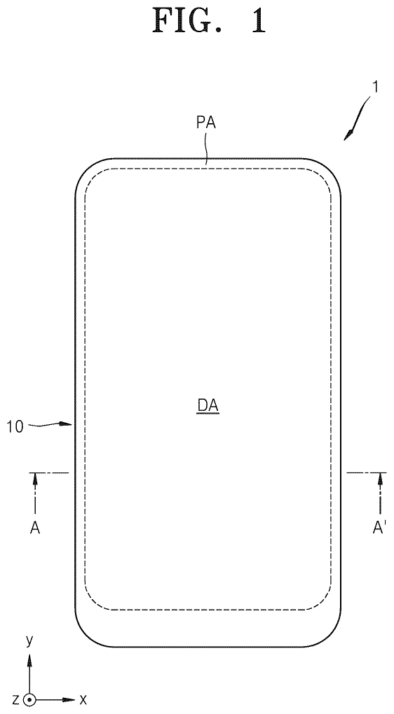

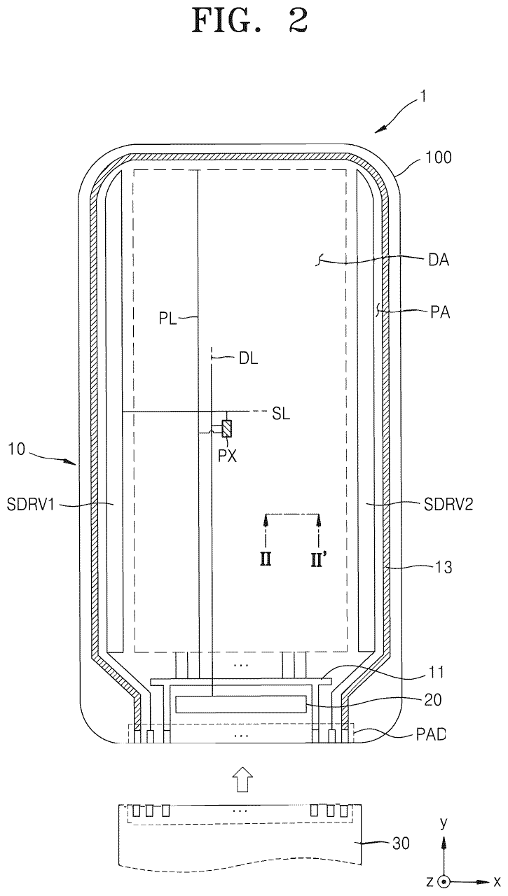

FIGS. 1 and 2 are plan views of a display apparatus 1 according to an embodiment.

Referring to FIG. 1, in an embodiment, the display apparatus 1 includes a display panel 10. The display apparatus 1 may be any of various products, such as a smartphone, a tablet computer, a laptop computer, a television, an advertisement board, etc.

The display panel 10 includes a display area DA and a peripheral area PA outside the display area DA. Because the display panel 10 includes a substrate 100 (see FIG. 2), the substrate 100 includes the display area DA and the peripheral area PA. However, the display area DA and the peripheral area PA may be defined in the substrate 100.

The display area DA is where images are displayed, and a plurality of sub-pixels are arranged in the display area DA. The display area DA may have one of various shapes, such as a circular shape, an elliptical shape, a polygonal shape, or a shape of a specific figure. FIG. 1 shows that the display area DA has, for example, an approximately rectangular shape with round edges.

The peripheral area PA is located outside the display area DA. The peripheral area PA surrounds at least a portion of the display area DA.

Hereinafter, although an organic light-emitting display apparatus is described as an example of the display apparatus 1 according to an embodiment, a display apparatus according to an embodiment of the disclosure is not necessarily limited thereto. In some embodiments, the display apparatus 1 is one of inorganic light-emitting display apparatus or a quantum-dot light-emitting display apparatus. For example, an emission layer of a display element of the display apparatus 1 includes one of an organic material, an inorganic material, quantum dots, an organic material and quantum dots, or an inorganic material and quantum dots.

Referring to FIG. 2, in an embodiment, the display panel 10 includes the substrate 100. Various elements that form the display panel 10 are disposed on the substrate 100. The substrate 100 includes at least one of glass, metal, or polymer resin. In an embodiment, the first substrate 100 includes a polymer resin such as at least one of polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure that includes two or more layers and a barrier layer disposed therebetween, where the two or more layers each include the polymer resin and the barrier layer includes an inorganic material. However, embodiments are not necessarily limited thereto, and various modifications can be made in other embodiments.

The substrate 100 includes the display area DA and the peripheral area PA outside the display area DA. In an embodiment of the present specification, when an element is located in the display area DA, it means that the element is arranged in the display area DA of the substrate 100 or overlaps the display area DA of the substrate 100. Likewise, in an embodiment of the present specification, when an element is located in the peripheral area PA, it means that the element is arranged in the peripheral area PA of the substrate 100 or overlaps the peripheral area PA of the substrate 100.

A plurality of sub-pixels PX are disposed in the display area DA. Each of the sub-pixels PX includes a light-emitting diode such as an organic light-emitting diode. Each sub-pixel PX emits, for example, one of red, green, blue, or white light.

Sub-pixel circuits that drive the sub-pixels PX are each connected to a signal line or a voltage line that controls turning-on/off, brightness, etc., of a light-emitting diode. For example, FIG. 2 shows, as signal lines, a scan line SL that extends in a first direction, such as an x direction, a data line DL that extends in a second direction that crosses the first direction, such as a y direction, and a driving voltage line PL as a voltage line.

The peripheral area PA is a non-display area in which images are not displayed. The peripheral area PA may entirely surround the display area DA. The peripheral area PA includes outer circuits that drive the sub-pixels PX. For example, a first scan driver SDRV1, a second scan driver SDRV2, a data driver 20, a terminal part PAD, a driving voltage supply line 11, and a common voltage supply line 13 are disposed in the peripheral area PA.

The first scan driver SDRV1 applies scan signals to each of sub-pixel circuits through the scan line SL, where the sub-pixel circuits drive the sub-pixels PX. The second scan driver SDRV2 is located opposite to the first scan driver SDRV1 with the display area DA therebetween, and extends approximately parallel to the first scan driver SDRV1. Some of the sub-pixel circuits in the display area DA are electrically connected to the first scan driver SDRV1, and the rest are electrically connected to the second scan driver SDRV2.

The data driver 20 includes an integrated circuit, such as a driving chip, that drives the display panel 10. Although the integrated circuit may be a data driving integrated circuit that generates data signals, embodiments of the disclosure are not necessarily limited thereto. The data driver 20 includes a plurality of terminals. The data driver 20 is electrically connected through the terminals to a printed circuit board 30 attached to one side of the display panel 10. In another embodiment, the data driver 20 is disposed on the printed circuit board 30.

The terminal part PAD is located on one side of the substrate 100. The terminal part PAD is exposed by not being covered by an insulating layer, and is connected to the printed circuit board 30.

A controller is disposed on the printed circuit board 30. The controller generates control signals that are transmitted to the first scan driver SDRV1 and the second scan driver SDRV2. In addition, the controller transmits a driving voltage ELVDD to the driving voltage supply line 11 and a common voltage ELVSS to the common voltage supply line 13. The driving voltage ELVDD is applied to the sub-pixel circuits of the sub-pixels PX through the driving voltage line PL connected to the driving voltage supply line 11, and the common voltage ELVSS is applied to an opposite electrode of the light-emitting diode connected to the common voltage supply line 13. The driving voltage supply line 11 extends in the first direction, such as the x direction, below the display area DA. The common voltage supply line 13 has a loop shape with one open side and partially surrounds the display area DA.

The controller generates a data signal, and the generated data signal is transmitted to the data line DL through the data driver 20. The data signal is sequentially transmitted to the sub-pixels PX in the same column through the data lines DL that extend in the second direction, such as the y direction. In addition, the controller generates a touch driving signal transmitted to sensor electrodes of a touch sensor layer.

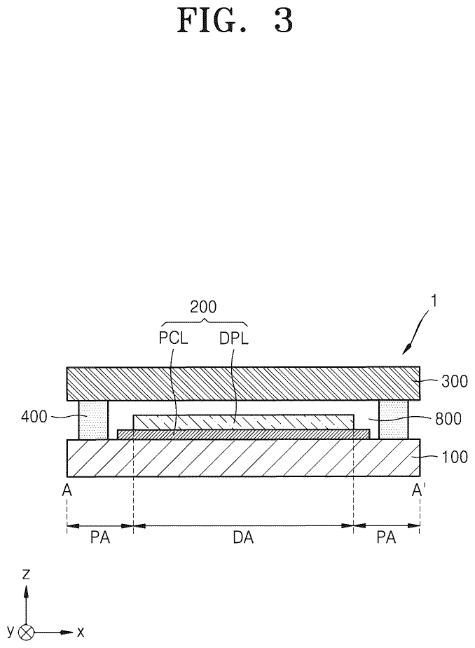

FIG. 3 is a schematic cross-sectional view of the display apparatus 1, taken along line A-A′ of FIG. 1, according to an embodiment.

Referring to FIG. 3, in an embodiment, the display apparatus 1 includes the substrate 100, a display layer 200, and a sealing structure.

The substrate 100 includes at least one of glass, metal, or a polymer resin.

The display layer 200 is disposed on the substrate 100. The display layer 200 includes a sub-pixel circuit layer PCL and a light-emitting diode layer DPL. The light-emitting diode layer DPL includes a light-emitting diode that corresponds to each sub-pixel. The sub-pixel circuit layer PCL includes a sub-pixel circuit electrically connected to the light-emitting diode, and a plurality of insulating layers. The light-emitting diode layer DPL is disposed on the sub-pixel circuit layer PCL, and the plurality of insulating layers are disposed between the sub-pixel circuit and the light-emitting diode. Some lines and some insulating layers of the sub-pixel circuit layer PCL extend to the peripheral area PA.

In an embodiment, the sealing structure includes a sealing substrate 300 and a sealing member 400. The sealing substrate 300 is disposed on the light-emitting diode layer DPL. For example, the light-emitting diode layer DPL is disposed between the substrate 100 and the sealing substrate 300. The sealing substrate 300 and the sealing member 400 block the light-emitting diode layer DPL from external moisture and the like.

The sealing substrate 300 is transparent. The sealing substrate 300 includes a glass that includes SiO₂ as a primary component or a resin such as reinforced plastic. In an embodiment, the sealing substrate 300 is a glass substrate. In an embodiment, the sealing substrate 300 is an encapsulation member.

The sealing member 400 is disposed between the substrate 100 and the sealing substrate 300 in the peripheral area PA. The sealing member 400 surrounds the display area DA. The sealing member 400 includes sealant or frit and bonds the substrate 100 to the sealing substrate 300 when being cured by heat and/or a laser beam. A filling member 800 is disposed in an inner space between the substrate 100 and the sealing substrate 300 and encapsulated by the sealing member 400.

The filling member 800 is disposed between the display layer 200 and the sealing substrate 300. The filling member 800 protects the display layer 200 from external impacts. The filling member 800 includes a transparent insulating material. In an embodiment, the filling member 800 includes an organic sealant such as at least one of urethane resin, epoxy resin, and acrylic resin, or an inorganic sealant such as silicon. In an embodiment, the filling member 800 includes polyimide. In an embodiment, the filling member 800 is omitted. When the filling member 800 is omitted, air fills the space between the display layer 200 and the sealing substrate 300.

In an embodiment, the sealing structure includes the sealing substrate 300, the sealing member 400, and an encapsulation layer. The encapsulation layer includes at least one inorganic encapsulation layer and at least one organic encapsulation layer. At least one inorganic encapsulation layer and at least one organic encapsulation layer are sequentially and alternately stacked. The inorganic encapsulation layer includes one or more inorganic materials, such as aluminum oxide, titanium oxide, tantalum oxide, zinc oxide, silicon oxide, silicon nitride, or silicon oxynitride. The organic encapsulation layer includes a polymer-based material. In an embodiment, the organic encapsulation layer includes acrylate.

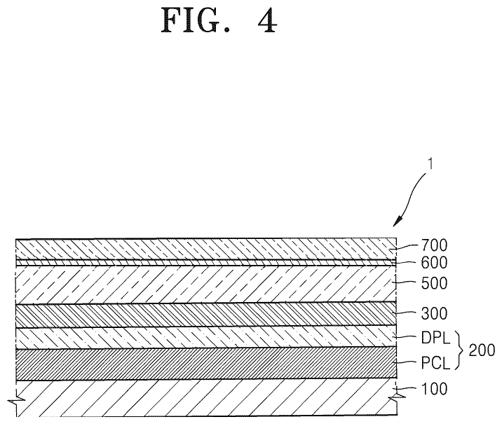

FIG. 4 is a schematic cross-sectional view of the display apparatus 1 according to an embodiment.

Referring to FIG. 4, in an embodiment, the display apparatus 1 includes the display layer 200 that forms the display area DA on the substrate 100. As described with reference to FIG. 3, the sealing substrate 300 covers the display layer 200. The sealing substrate 300 protects the display layer 200 from external moisture, oxygen, etc., in cooperation with the sealing member 400 (see FIG. 3) in the peripheral area PA.

A touch sensor layer 500 is disposed on the sealing substrate 300. The touch sensor layer 500 includes a plurality of conductive sensor electrodes. For example, the touch sensor layer 500 is a capacitive-type sensor layer. The touch sensor layer 500 is used to output coordinates of a location where an object approaches or touches by using a change in capacitance that occurs when the object, such as the user's hand, approaches or touches the surface of the touch sensor layer 500.

An optical functional layer may be disposed between the touch sensor layer 500 and a cover window 700. The optical functional layer includes an anti-reflection functional layer. The anti-reflection functional layer includes a phase retarder and a polarizer or a black matrix and color filters.

The cover window 700 is disposed over the touch sensor layer 500 (or the optical functional layer) with an adhesive layer 600 therebetween. The adhesive layer 600 includes a transparent optical clear adhesive (OCA).

The cover window 700 may be flexible. For example, the cover window 700 is one of a plastic window such as a polyimide window or an ultra-thin glass window.

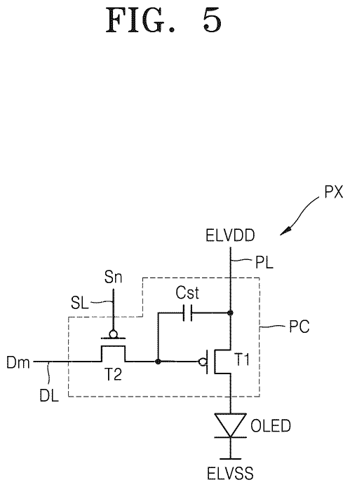

FIG. 5 is a schematic circuit diagram of a light-emitting diode of a pixel of a display apparatus and a sub-pixel circuit PC connected to the light-emitting diode, according to an embodiment.

Referring to FIG. 5, in an embodiment, the sub-pixel circuit PC is connected to a light-emitting diode such as an organic light-emitting diode OLED to control light emission of the sub-pixels PX. The sub-pixel circuit PC includes a driving thin-film transistor T1, a switching thin-film transistor T2, and a storage capacitor Cst. The switching thin-film transistor T2 is connected to the scan line SL and the data line DL and transmits a data signal Dm to the driving thin-film transistor T1 according to a scan signal Sn, wherein the data signal Dm is received through the data line DL, and the scan signal Sn is received through the scan line SL.

The storage capacitor Cst is connected to the switching thin-film transistor T2 and the driving voltage line PL and stores a voltage that corresponds to the difference between a voltage received from the switching thin-film transistor T2 and the driving voltage ELVDD received through the driving voltage line PL.

The driving thin-film transistor T1 is connected to the driving voltage line PL and the storage capacitor Cst and controls a driving current according to the voltage stored in the storage capacitor Cst, where the driving current flows from the driving voltage line PL to the organic light-emitting diode OLED. The organic light-emitting diode OLED emits light having a brightness that corresponds to the driving current.

The sub-pixel circuit PC is not limited to the number of thin-film transistors, the number of storage capacitors, and the circuit design described with reference to FIG. 5, and the number of thin-film transistors, the number of storage capacitors, and the circuit design may be variously changed in other embodiments.

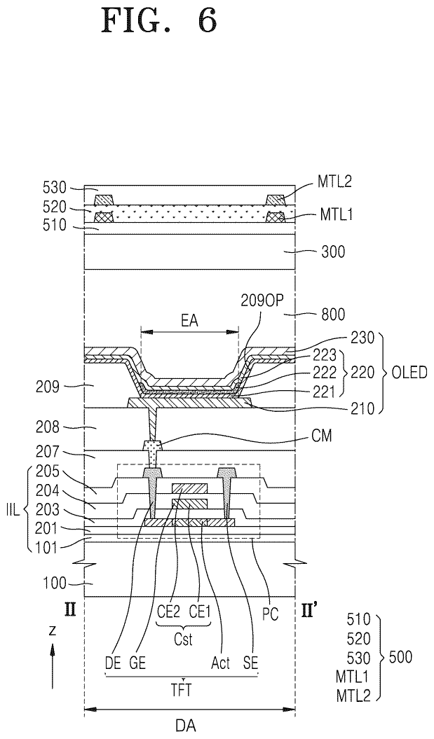

FIG. 6 is a schematic cross-sectional view of the display area DA of the display apparatus 1, taken along line II-Il′ of FIG. 2, according to an embodiment.

Referring to FIG. 6, in an embodiment, the organic light-emitting diode OLED and the sub-pixel circuit PC electrically connected to the organic light-emitting diode OLED are arranged in the display area DA of the substrate 100.

A buffer layer 201 is disposed on the substrate 100, and reduces or blocks penetration of foreign materials, moisture, or external air from below the substrate 100, and provides a flat surface on the substrate 100. The buffer layer 201 may include an inorganic material, an organic material, or an organic/inorganic composite material and may include a single layer or multiple layers that include an inorganic material and an organic material, where the inorganic material includes oxide or nitride.

A barrier layer 101 is further disposed between the substrate 100 and the buffer layer 201. The barrier layer 101 blocks penetration of external air. In an embodiment, the buffer layer 201 includes silicon oxide or silicon nitride.

The sub-pixel circuit PC is disposed on the buffer layer 201, and the sub-pixel circuit PC includes a thin-film transistor TFT and a storage capacitor Cst. The thin-film transistor TFT includes a semiconductor layer Act, a gate electrode GE, a drain electrode DE, and a source electrode SE.

The semiconductor layer Act is disposed on the buffer layer 201 and includes polycrystalline silicon. In an embodiment, the semiconductor layer Act includes amorphous silicon. In an embodiment, the semiconductor layer Act includes an oxide of at least one of indium (In), gallium (Ga), tin (Sn), zirconium (Zr), vanadium (V), hafnium (Hf), cadmium (Cd), germanium (Ge), chromium (Cr), titanium (Ti), or zinc (Zn). The semiconductor layer Act includes a channel region, a source region, and a drain region. The source region and the drain region are doped with impurities.

A first gate insulating layer 203 is disposed on the buffer layer 201 and covers the semiconductor layer Act. The first gate insulating layer 203 includes an inorganic insulating material such as at least one of silicon oxide, silicon nitride, silicon oxynitride, aluminum oxide, titanium oxide, tantalum oxide, hafnium oxide, or zinc oxide. The first gate insulating layer 203 may include a single layer or multiple layers that include the inorganic insulating material.

The gate electrode GE is disposed on the first gate insulating layer 203 and overlaps the semiconductor layer Act. The gate electrode GE includes at least one of molybdenum (Mo), aluminum (AI), copper (Cu), or titanium (Ti), etc., and may include a single layer or multiple layers. For example, the gate electrode GE includes a single Mo layer.

A second gate insulating layer 204 is disposed on the first gate insulating layer 203 and covers the gate electrode GE. The second gate insulating layer 204 includes an inorganic insulating material such as at least one of silicon oxide, silicon nitride, silicon oxynitride, aluminum oxide, titanium oxide, tantalum oxide, hafnium oxide, or zinc oxide. The second gate insulating layer 204 may include a single layer or multiple layers that include the inorganic insulating material.

A second capacitor electrode CE2 of the storage capacitor Cst is disposed on the second gate insulating layer 204. The second capacitor electrode CE2 overlaps the gate electrode GE. The gate electrode GE and the second upper electrode CE2 that overlap each other with the second gate insulating layer 204 therebetween constitute the storage capacitor Cst. For example, the gate electrode GE is a first capacitor electrode CE1 of the storage capacitor Cst.

The second capacitor electrode CE2 includes at least one of aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu) and include a single layer or multiple layers that include the above materials.

An interlayer insulating layer 205 is disposed on the second gate insulating layer 204 and covers the second capacitor electrode CE2. The interlayer insulating layer 205 includes an inorganic insulating material such as at least one of silicon oxide, silicon nitride, silicon oxynitride, aluminum oxide, titanium oxide, tantalum oxide, hafnium oxide, or zinc oxide. The interlayer insulating layer 205 may include a single layer or multiple layers that include the inorganic insulating material.

The barrier layer 101, the buffer layer 201, the first gate insulating layer 203, the second gate insulating layer 204, and the interlayer insulating layer 205 may be referred to as inorganic insulating layers IIL.

The source electrode SE and the drain electrode DE are disposed on the interlayer insulating layer 205. The source electrode SE and the drain electrode DE each include a conductive material, such as at least one of molybdenum (Mo), aluminum (AI), copper (Cu), or titanium (Ti), and may include a single layer or multiple layers that include the above materials. For example, the source electrode SE and the drain electrode DE have a multi-layered structure of Ti/Al/Ti. In an embodiment, the source electrode SE or the drain electrode DE are omitted. For example, adjacent thin-film transistors TFT share the source region or the drain region of the semiconductor layer Act. The source region or the drain region serves as the source electrode SE or the drain electrode DE.

A first organic insulating layer 207 and a second organic insulating layer 208 are sequentially disposed on the interlayer insulating layer 205 and cover the source electrode SE and the drain electrode DE. The second organic insulating layer 208 has a flat upper surface such that a sub-pixel electrode 210 disposed thereon is formed flat.

The first organic insulating layer 207 and the second organic insulating layer 208 each include an organic material. The first organic insulating layer 207 and the second organic insulating layer 208 each include an organic insulating material such as a general-purpose polymer such as at least one of benzocyclobutene (BCB), polyimide, hexamethyldisiloxane (HMDSO), polymethylmethacrylate (PMMA) or polystyrene (PS), polymer derivatives that have a phenol-based group, an acryl-based polymer, an imide-based polymer, an aryl ether-based polymer, an amide-based polymer, a fluorine-based polymer, a p-xylene-based polymer, or a vinyl alcohol-based polymer. When forming the first organic insulating layer 207 and the second organic insulating layer 208, to provide a flat upper surface after the layers are formed, chemical mechanical polishing is performed on the upper surface of the layers.

A connection electrode CM is disposed on the first organic insulating layer 207. The first organic insulating layer 207 has a contact hole that exposes one of the source electrode SE or the drain electrode DE of the thin-film transistor TFT, and the connection electrode CM is electrically connected to the thin-film transistor TFT by being in contact with the source electrode SE or the drain electrode DE through the contact hole.

The connection electrode CM includes a conductive material such as at least one of molybdenum (Mo), aluminum (AI), copper (Cu), or titanium (Ti), etc., and may have a single-layered structure or a multi-layered structure that includes the above materials.

The sub-pixel electrode 210 is disposed on the second organic insulating layer 208. The second organic insulating layer 208 has a contact hole that exposes the connection electrode CM, and the sub-pixel electrode 210 is electrically connected to the thin-film transistor TFT by being in contact with the connection electrode CM through the contact hole.

The sub-pixel electrode 210 includes a conductive oxide such as at least one of indium tin oxide (ITO), indium zinc oxide (IZO), zinc oxide (ZnO), indium oxide (In₂O₃), indium gallium oxide (IGO), or aluminum zinc oxide (AZO). The sub-pixel electrode 210 may include a reflective layer that includes at least one of silver (Ag), magnesium (Mg), aluminum (Al), platinum (Pt), palladium (Pd), gold (Au), nickel (Ni), neodymium (Nd), iridium (Ir), or chrome (Cr), or a compound thereof. For example, the sub-pixel electrode 210 has a structure that includes layers on/under the reflective layer, where the layers include ITO, IZO, ZnO, or In₂O₃. For example, the sub-pixel electrode 210 has a stack structure of ITO/Ag/ITO.

A bank layer 209 is disposed on the second organic insulating layer 208 and covers edges of the sub-pixel electrode 210 and has an opening 209OP that exposes the central portion of the sub-pixel electrode 210. An emission area EA of the organic light-emitting diode OLED, such as a size and shape of the sub-pixel, are defined by the opening 209OP.

The bank layer 209 prevents arcs, etc., from occurring at the edges of the sub-pixel electrode 210 by increasing a distance between the edges of the sub-pixel electrode 210 and an opposite electrode 230 disposed over the sub-pixel electrode 210. The bank layer 209 includes an organic insulating material such as at least one of polyamide, acryl resin, benzocyclobutene, or hexamethyldisiloxane (HMDSO), and is formed by spin coating, etc.

The bank layer 209 is black. The bank layer 209 includes a black light-blocking material. The light-blocking material includes at least one of carbon black, carbon nanotubes, resin or a paste that includes a black dye, metal particles such as at least one of nickel (Ni), aluminum (Al), or molybdenum (Mo), or an alloy thereof, metal oxide particles such as chrome oxide, or metal nitride particles such as chrome nitride. When the bank layer 209 includes a light-blocking material, external light reflection by metal structures disposed below the bank layer 209 is reduced.

An intermediate layer 220 includes an emission layer 222, a first functional layer 221, and a second functional layer 223. The emission layer 222 is disposed in the opening 209OP of the bank layer 209 and corresponds to the sub-pixel electrode 210. The emission layer 222 includes a polymer material or a low-molecular weight material and emit one of red, green, blue, or white light.

The first functional layer 221 and the second functional layer 223 are respectively disposed under and/or on the emission layer 222. In an embodiment, unlike the emission layer 222 patterned for each sub-pixel, the first functional layer 221 and the second functional layer 223 are integrally provided in the entire display area DA.

The first functional layer 221 may include a single layer or multiple layers. For example, when the first functional layer 221 includes a polymer material, the first functional layer 221 include a hole transport layer (HTL), which has a single-layered structure, and includes polyethylene dihydroxythiophene (PEDOT: poly-(3,4)-ethylene-dihydroxy thiophene) or polyaniline (PANI: polyaniline). When the first functional layer 221 includes a low-molecular weight material, the first functional layer 221 includes a hole injection layer (HIL) and an HTL.

The second functional layer 223 may be omitted. For example, when the first functional layer 221 and the emission layer 222 include a polymer material, the second functional layer 223 should be formed. The second functional layer 223 may include a single layer or multiple layers. The second functional layer 223 includes an electron transport layer (ETL) and/or an electron injection layer (EIL). In an embodiment, at least one of an HIL, an HTL, an ETL, and an EIL is omitted.

The opposite electrode 230 is integrally provided in the entire display area DA. The opposite electrode 230 includes a conductive material that has a relatively low work function. For example, the opposite electrode 230 includes a (semi) transparent layer that includes at least one of silver (Ag), magnesium (Mg), aluminum (Al), nickel (Ni), chromium (Cr), lithium (Li), or calcium (Ca), or an alloy thereof. In some embodiments, the opposite electrode 230 further includes a layer on the (semi) transparent layer that includes one of ITO, IZO, ZnO, or In₂O₃. In an embodiment, the opposite electrode 230 includes silver (Ag) and/or magnesium (Mg). A stack structure of the sub-pixel electrode 210, the intermediate layer 220, and the opposite electrode 230 that are sequentially stacked forms the organic light-emitting diode OLED.

In an embodiment, a capping layer is disposed on the organic light-emitting diode OLED. The capping layer increases the light-emission efficiency of the organic light-emitting diode OLED based on a constructive interference principle. The capping layer may be an organic capping layer that includes an organic material, an inorganic capping layer that includes an inorganic material, or a composite capping layer that includes an organic material and an inorganic material.

The sealing substrate 300 is disposed on the organic light-emitting diode OLED. The sealing substrate 300 covers the entire display area DA and extends to the peripheral area PA and covers at least a portion of the peripheral area PA. As described above with reference to FIG. 3, an inner space between the substrate 100 and the sealing substrate 300 is encapsulated by the sealing member 400 (see FIG. 3) in the peripheral area PA. The filling member 800 is disposed between the organic light-emitting diode OLED and the sealing substrate 300.

The touch sensor layer 500 has a multi-layered structure. The touch sensor layer 500 includes a sensor electrode, a trace line, and at least one insulating layer. The touch sensor layer 500 senses an external input by using, for example, a capacitive method. As described above, an operation method of the touch sensor layer 500 is not particularly limited. In an embodiment, the touch sensor layer 500 senses an external input by using at least one of an electromagnetic induction method or a pressure sensing method.

In an embodiment, the touch sensor layer 500 includes a first touch insulating layer 510, a first touch conductive layer MTL1, a second touch insulating layer 520, a second touch conductive layer MTL2, and a third touch insulating layer 530.

The first touch insulating layer 510 is directly disposed on the sealing substrate 300. The first touch insulating layer 510 prevents damage to the sealing substrate 300 and blocks interference signals that can occur when the touch sensor layer 500 is driven. In an embodiment, the first touch insulating layer 510 is omitted.

The first touch conductive layer MTL1 is disposed on the first touch insulating layer 510. The second touch insulating layer 520 is disposed on the first touch insulating layer 510 and covers the first conductive layer MTL1. The second touch conductive layer MTL2 is disposed on the second touch insulating layer 520.

Each of the first touch conductive layer MTL1 and the second touch conductive layer MTL2 includes a metal or a transparent conductive material. The metal includes, for example, at least one of molybdenum (Mo), silver (Ag), titanium (Ti), copper (Cu), or aluminum (Al), or an alloy thereof. The transparent conductive material includes a transparent conductive oxide such as at least one of indium tin oxide (ITO), indium zinc oxide (IZO), zinc oxide (ZnO), or indium tin zinc oxide (ITZO). Each of the first touch conductive layer MTL1 and the second touch conductive layer MTL2 may include a single-layered structure or a multi-layered structure. In an embodiment, the first touch conductive layer MTL1 and the second touch conductive layer MTL2 each include a metal layer and have a three-layered structure of Ti/Al/Ti.

Each of the first touch conductive layer MTL1 and the second touch conductive layer MTL2 includes a plurality of patterns. The first touch conductive layer MTL1 includes first conductive patterns, and the second touch conductive layer MTL2 includes second conductive patterns. The first conductive patterns and the second conductive patterns form the sensor electrode.

The first touch conductive layer MTL1 and the second touch conductive layer MTL2 are electrically connected to each other through a contact hole formed in an insulating layer between the first touch conductive layer MTL1 and the second touch conductive layer MTL2, such as the second touch insulating layer 520. In an embodiment, the first touch conductive layer MTL1 and the second touch conductive layer MTL2 have a mesh structure through which light emitted from the organic light-emitting diode OLED passes. For example, the first touch conductive layer MTL1 and the second touch conductive layer MTL2 may not overlap the emission area EA.

The third touch insulating layer 530 is disposed on the second touch insulating layer 520 and covers the second touch conductive layer MTL2. The first touch insulating layer 510, the second touch insulating layer 520, and the third touch insulating layer 530 may each include an inorganic material or an organic material. The organic material includes at least one of an acryl-based resin, a methacryl-based resin, a polyisoprene, a vinyl-based resin, an epoxy-based resin, a urethane-based resin, a cellulose-based resin, or a perylene-based resin. The inorganic material includes at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride. The first touch insulating layer 510, the second touch insulating layer 520, and the third touch insulating layer 530 may each include a single-layer or multiple layers.

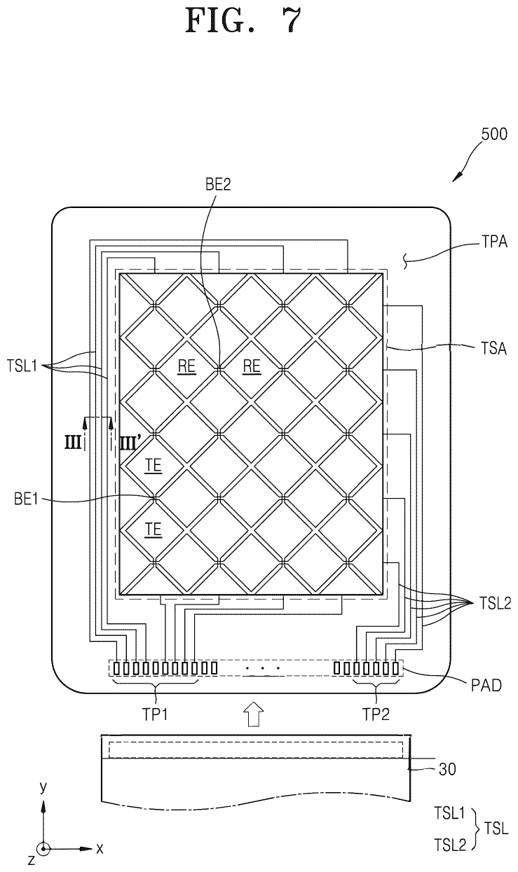

FIG. 7 is a plan view of a touch sensor layer of a display apparatus according to an embodiment.

Referring to FIG. 7, in an embodiment, the touch sensor layer 500 includes a touch sensor area TSA and a touch peripheral area TPA, where the touch sensor area TSA senses a user's touch, and the touch peripheral area TPA is disposed around the touch sensor area TSA. The touch sensor area TSA overlaps the display area DA of the substrate 100, and the touch peripheral area TPA overlaps the peripheral area PA of the substrate 100.

FIG. 7 shows the sensor electrodes, the trace lines TSL connected to the sensor electrodes, and sensor terminals of the touch sensor layer 500. The sensor electrodes are included in the first touch conductive layer MTL1 (see FIG. 6) and the second touch conductive layer MTL2 (see FIG. 6). The sensor electrodes include a driving electrode TE and a sensing electrode RE. The trace lines TSL include a first trace line TSL1 and a second trace line TSL2. The sensor terminals include a first sensor terminal TP1 and a second sensor terminal TP2.

In an embodiment, each of the driving electrode TE and the sensing electrode RE has a rhombus planar shape, but embodiments are not necessarily limited thereto. For convenience of description, although FIG. 7 shows that the driving electrode TE and the sensing electrode RE have a rhombus planar shape, the driving electrode TE, the sensing electrode RE, a first touch connection electrode BE1, and a second touch connection electrode BE2 may be formed in a mesh structure or a net structure in a plan view. The sensing electrodes RE extend in the first direction (e.g., the x direction) and are electrically connected to each other. The driving electrodes TE extend in the second direction (e.g., the y direction) that crosses the first direction (e.g., the x direction) and are electrically connected to each other. The driving electrodes TE may be arranged apart from the sensing electrodes RE. The driving electrodes TE are arranged side-by-side in the first direction (e.g., the x direction). In intersection regions of the sensing electrodes RE and the driving electrodes TE, driving electrodes TE adjacent to each other in the second direction (e.g., the y direction) are connected to each other through the first touch connection electrode BE1, and sensing electrodes RE adjacent to each other in the first direction (e.g., the x direction) are connected to each other through the second touch connection electrode BE2.

In an embodiment, the driving electrode TE, the sensing electrode RE, and the second touch connection electrode BE2 are provided in the second touch conductive layer MTL2 (see FIG. 6), and the first touch connection electrode BE1 is provided in the first touch conductive layer MTL1 (see FIG. 6). In another embodiment, the driving electrode TE, the sensing electrode RE, and the second touch connection electrode BE2 are provided in the first touch conductive layer MTL1, and the first touch connection electrode BE1 is provided in the second touch conductive layer MTL2.

The first trace line TSL1 and the second trace line TSL2 are disposed in the touch peripheral area TPA. The driving electrodes TE in the touch sensor area TSA are connected to the first trace lines TSL1. The first trace lines TSL1 are connected to the first sensor terminal TP1. The driving electrodes TE receive a touch driving signal through the first trace lines TSL1. One end of each of the sensing electrodes RE is connected to a corresponding second trace line TSL2. The second trace lines TSL2 are connected to the second sensor terminals TP2.

The first sensor terminals TP1 and the second sensor terminals TP2 are disposed in the touch peripheral area TPA. The first sensor terminals TP1 and the second sensor terminals TP2 are disposed in the terminal part PAD arranged on one side of the display panel 10. In an embodiment, the printed circuit board 30 is disposed on the first sensor terminals TP1 and the second sensor terminals TP2.

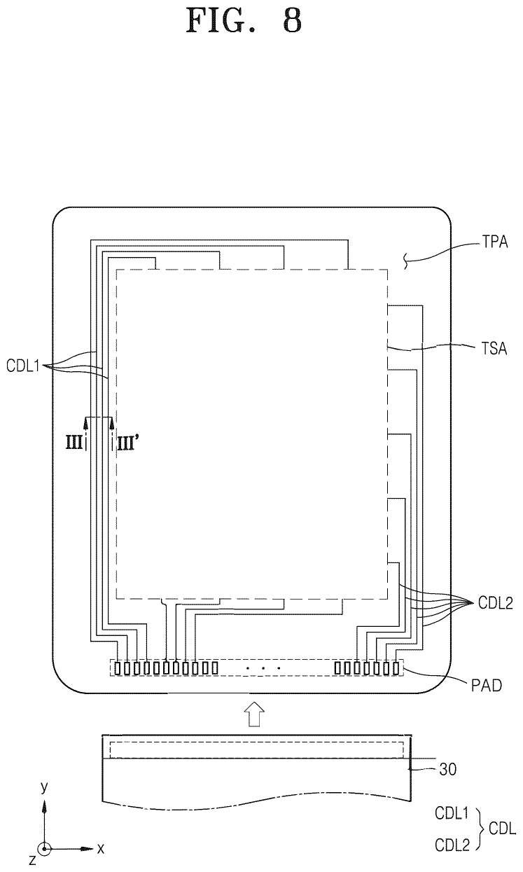

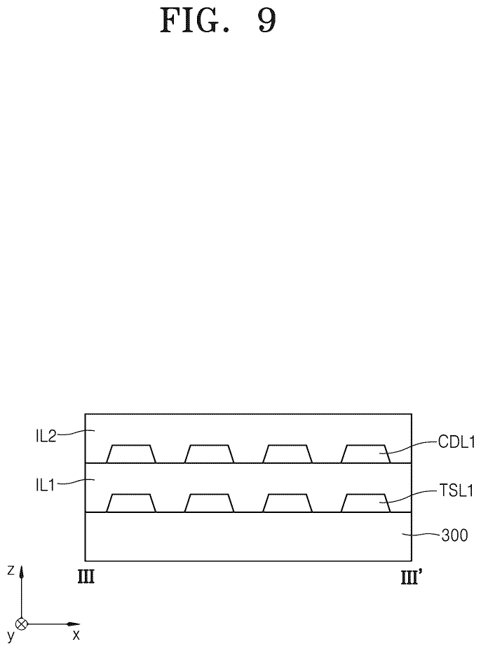

FIG. 8 is a plan view of an inspection line of a display apparatus according to an embodiment. FIG. 9 is a schematic cross-sectional view of the peripheral area PA of the display apparatus 1, taken along line III-III′ of FIGS. 7 and 8, according to an embodiment.

Referring to FIGS. 7 and 8, in an embodiment, inspection lines CDL is disposed on the trace lines TSL of the touch sensor layer 500. The inspection lines CDL overlap the trace lines TSL. In an embodiment, the inspection lines CDL include a first inspection line CDL1 and a second inspection line CDL2, where the first inspection line CDL1 overlaps the first trace line TSL1, and the second inspection line CDL2 overlaps the second trace line TSL2. The inspection lines CDL overlap the trace lines TSL in one-to-one correspondence.

In an embodiment, the inspection lines CDL completely overlap respective corresponding trace lines TSL. For example, the first inspection line CDL1 completely overlaps the first trace line TSL1. The second inspection line CDL2 completely overlaps the second trace line TSL2. For example, the inspection lines CDL have the same pattern as the trace lines TSL in a plan view. For example, the first inspection line CDL1 has the same pattern as the first trace line TSL1 in a plan view. The second inspection line CDL2 has the same pattern as the second trace line TSL2 in a plan view. In an embodiment, the width of the inspection line CDL is substantially the same as the width of the trace line TSL. For example, the width of the first inspection line CDL1 is substantially the same as the width of the first trace line TSL1. The width of the second inspection line CDL2 is substantially the same as the width of the second trace line TSL2.

In an embodiment, the number of inspection lines CDL is equal to the number of trace lines TSL. For example, FIG. 8 shows that eight inspection lines CDL that include four first inspection lines CDL1 and four second inspection lines CDL2 correspond to eight trace lines TSL, which include four first trace lines TSL1 and four second trace lines TSL2. However, embodiments of the disclosure are not necessarily limited thereto. The number of inspection lines CDL and the number of trace lines TSL may be less than eight or greater than eight in other embodiments.

The inspection lines CDL are disposed in the touch peripheral area TPA. The inspection lines CDL are connected to the terminal part PAD. In an embodiment, the printed circuit board 30 is disposed on the terminal part PAD to which the inspection lines CDL are connected.

FIG. 9 is a cross-sectional view of the peripheral area PA, taken along line III-III′ of FIGS. 7 and 8 and shows the sealing substrate 300, the trace lines TSL, and the inspection lines CDL that overlap the trace lines TSL in the touch peripheral area TPA. Although FIG. 9 shows, as an example of the trace lines TSL and the inspection lines CDL, the first trace lines TSL1 and the first inspection lines CDL1 disposed on the sealing substrate 300, the second trace lines TSL2 and the second inspection lines CDL2 have the same cross-sectional structure.

Referring to FIG. 9, in an embodiment, the first trace lines TSL1 are disposed on the sealing substrate 300. In addition, in another embodiment, an insulating layer is further disposed between the sealing substrate 300 and the first trace lines TSL1.

The inspection lines CDL are insulated from the trace lines TSL. For example, the first inspection lines CDL1 are disposed over the first trace lines TSL1 with a first insulating layer IL1 interposed therebetween. A second insulating layer IL2 is disposed on the first insulating layer IL1 and the first inspection lines CDL1.

Each of the first insulating layer IL1 and the second insulating layer IL2 may include an inorganic material or an organic material. In an embodiment, the first insulating layer IL1 and the second insulating layer IL2 respectively correspond to the second touch insulating layer 520 and the third touch insulating layer 530 shown in FIG. 6. The organic material includes at least one of an acryl-based resin, a methacryl-based resin, a polyisoprene, a vinyl-based resin, an epoxy-based resin, a urethane-based resin, a cellulose-based resin, or a perylene-based resin. The inorganic material includes at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride. Each of the first insulating layer IL1 and the second insulating layer IL2 may include a single layer or multiple layers. In an embodiment, each of the first insulating layer IL1 and the second insulating layer IL2 includes a single layer of silicon oxide.

The first trace line TSL1 includes a metal. The metal includes, for example, at least one of molybdenum (Mo), silver (Ag), titanium (Ti), copper (Cu), aluminum (Al), or an alloy thereof. The first trace line TSL1 may include a single-layered structure or a multi-layered structure.

As described above, the first trace line TSL1 is electrically connected to some of the sensor electrodes of the touch sensor layer 500 (see FIG. 7). In an embodiment, the first trace line TSL1 is provided in one of the first touch conductive layer MTL1 (see FIG. 6) or the second touch conductive layer MTL2 (see FIG. 6) that extends from the display area DA to the peripheral area PA. For example, the first touch conductive layer MTL1 (see FIG. 6) or the second touch conductive layer MTL2 (see FIG. 6) are metal layers. The first trace line TSL1 includes the same material as at least some of the sensor electrodes, such as the driving electrodes TE (see FIG. 7) or the sensing electrodes RE (see FIG. 7). In an embodiment, the first trace line TSL1 has a multi-layered structure of Ti/Al/Ti.

The first inspection line CDL1 includes a different material from that of the first trace line TSL1. In an embodiment, the first inspection line CDL1 includes a conductive oxide. For example, the first inspection line CDL1 includes a transparent conductive oxide such as indium tin oxide (ITO), indium zinc oxide (IZO), zinc oxide (ZnO), or indium tin zinc oxide (ITZO). The first inspection line CDL1 may include a single-layered structure or a multi-layered structure. In an embodiment, the first inspection line CDL1 has a single-layered structure of ITO.

The trace line TSL is connected to the terminal part PAD, and a change in resistance of the trace line TSL can be measured through the terminal part PAD or the printed circuit board connected to the terminal part PAD. Because the trace lines TSL are metal layers, even when fine scratches or short-circuit defects occur in at least some of the trace lines TSL, resistance is only slightly changed. Accordingly, determining whether fine scratches or short-circuit defects occur in at least some of the trace lines TSL may be challenging.

When fine scratches or short-circuit defects occur in at least some of the trace lines TSL of the display apparatus 1, when the display apparatus 1 is exposed to a high temperature and a high humidity environment during a reliability evaluation process, moisture can penetrate into the fine scratches or short-circuit defects, causing corrosion, and the corresponding trace line TSL can malfunction. Accordingly, defects in the display apparatus 1 may occur.

In contrast, the display apparatus 1 according to an embodiment includes the inspection line CDL disposed on the trace line TSL. The inspection line CDL overlaps the trace line TSL and is connected to the terminal part PAD, and a resistance change of the inspection line CDL can be measured through the terminal part PAD or the printed circuit board connected to the terminal part PAD. Because the inspection line CDL includes a different conductive oxide from the trace line TSL, when fine scratches or short-circuit defects occur in some of the inspection lines CDL, resistance changes are relatively large. Accordingly, determining whether fine scratches or short-circuit defects occur in at least some of the inspection lines CDL is easier.

Because the inspection line CDL is disposed on and overlaps the trace line TSL in the same pattern as the trace line TSL, fine scratches or short-circuit defects also occur in the trace line TSL that corresponds to the inspection line CDL in which fine scratches or short-circuit defects occur. Accordingly, whether defects, that is, fine scratches or short-circuit defects, occur in the trace line TSL can be determined by measuring resistance changes in the inspection line CDL.

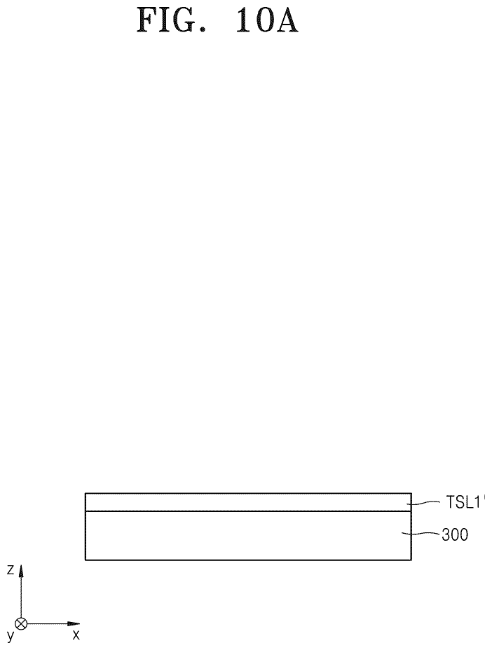

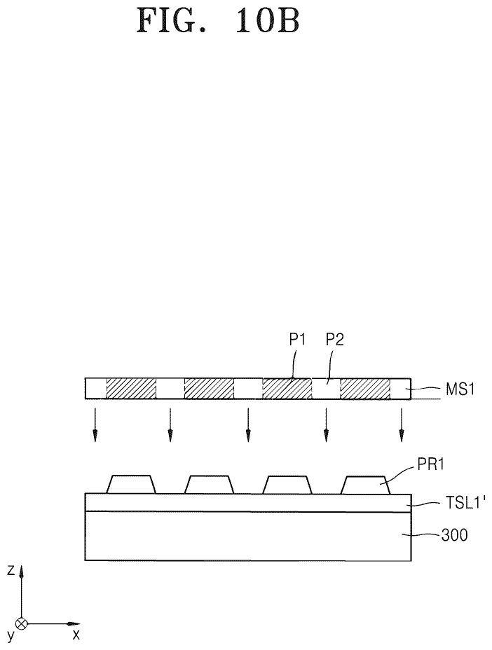

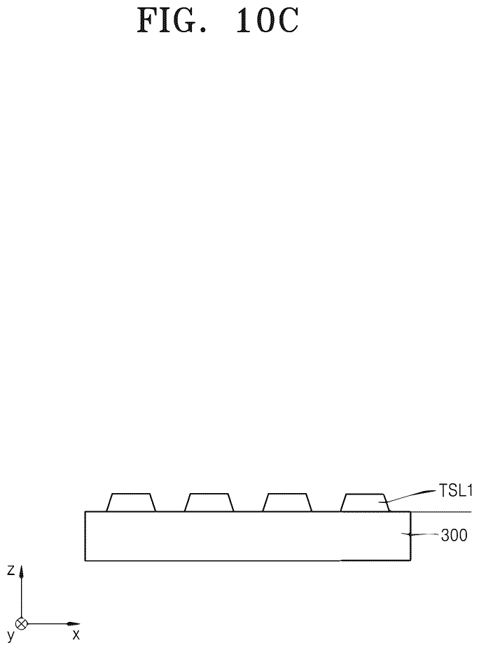

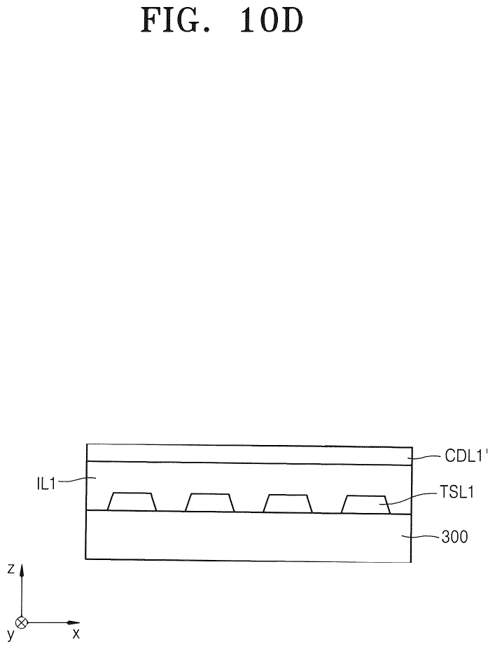

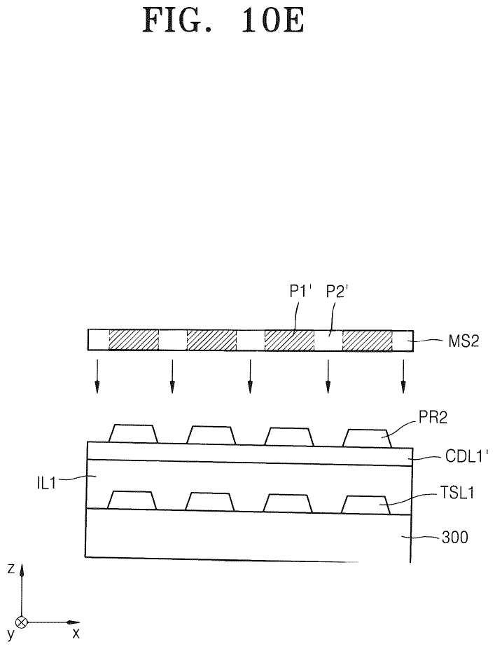

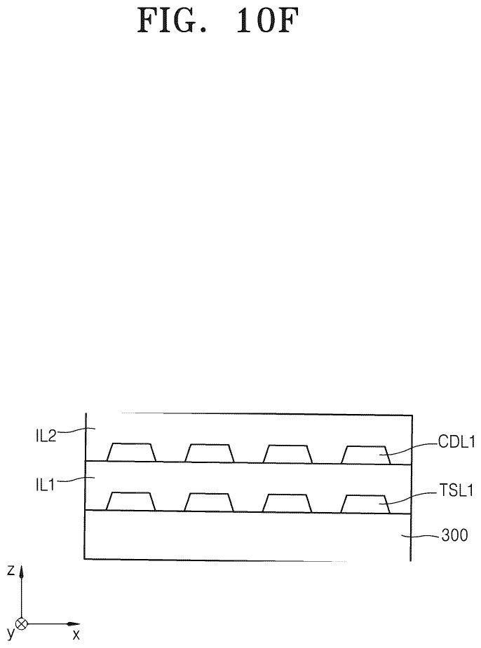

FIGS. 10A to 10F are cross-sectional views that illustrate a process of manufacturing a display apparatus according to an embodiment, and show manufacturing processes of a cross-sectional structure of FIG. 9. FIGS. 10A to 10F show an example of the trace line TSL and the inspection line CDL, and for convenience of description, illustrate the process of manufacturing the first trace line TSL1 and the first inspection line CDL1.

Referring to FIGS. 10A and 10B, in an embodiment, a first conductive layer TSL1′ is formed on the sealing substrate 300. The first conductive layer TSL1′ includes a metal. The sealing substrate 300 is formed on a substrate that includes a display area and a peripheral area, and a touch sensor layer is formed on the sealing substrate 300. Forming the touch sensor layer includes forming driving electrodes and sensing electrodes.

A first photoresist pattern PR1 is formed on the first conductive layer TSL1′. The first photoresist pattern PR1 has a pattern that corresponds to the first trace line TSL1 (see FIG. 9) and is formed through an exposure and developing processes that uses a mask. For example, the first photoresist pattern PR1 is formed by patterning a first photoresist layer. The first photoresist layer includes a photoresist. Although the first photoresist layer includes a positive-type photoresist as an example, the first photoresist layer may include a negative-type photoresist. A first mask MS1 includes a first portion P1 and a second portion P2. The first portion P1 is a light-blocking portion, and the second portion P2 is a light-transmissive portion. The first photoresist pattern PR1 is formed by exposing and developing the first photoresist layer with different exposure times for each portion through the first mask MS1.

Referring to FIG. 10C, in an embodiment, the first conductive layer TSL1′ is etched using the first photoresist pattern PR1 as a mask. During the etching process, a portion of the first conductive layer TSL1′ is removed to form the first trace lines TSL1.

Referring to FIG. 10D, in an embodiment, the first insulating layer IL1 is disposed on the first trace lines TSL1. A second conductive layer CDL1′ is disposed on the first insulating layer IL1. In an embodiment, the second conductive layer CDL1′ includes a conductive oxide. In an embodiment, the second conductive layer CDL1′ includes ITO.

Referring to FIG. 10E, in an embodiment, a second photoresist pattern PR2 is formed on the second conductive layer CDL1′. The second photoresist pattern PR2 has a pattern that corresponds to the first inspection line CDL1 (see FIG. 9) and is formed through exposure and developing processes that use a mask. For example, the second photoresist pattern PR2 is formed by patterning a second photoresist layer. For example, the second photoresist layer includes a positive-type photoresist. A second mask MS2 includes a first portion P1′ and a second portion P2′. The first portion P1′ is a light-blocking portion, and the second portion P2′ is a light-transmissive portion. The second photoresist pattern PR2 is formed by exposing and developing the second photoresist layer with different exposure time for each portion through the second mask MS2.

In an embodiment, the second mask MS2 is the as the first mask MS1. For example, the second photoresist pattern PR2 is the same as the first photoresist pattern PR1.

Referring to FIG. 10F, in an embodiment, the second conductive layer CDL1′ is etched using the second photoresist pattern PR2 as a mask. During the etching process, a portion of the second conductive layer CDL1′ is removed to form the first inspection lines CDL1.

In an embodiment, the first inspection line CDL1 is patterned using the same mask as that used for the first trace line TSL1. In an embodiment, the first inspection lines CDL1 overlaps the first trace lines TSL1. The first inspection lines CDL1 completely overlap the first trace line TSL1. For example, the first inspection lines CDL1 have the same pattern as the first trace lines TSL1. The number of first inspection lines CDL1 is the same as the number of the first trace lines TSL1.

In an embodiment, because the first inspection line CDL1 is patterned using the same mask as that used for the first trace line TSL1, the process is economical. In addition, because the display apparatus includes the first inspection line CDL1 with the same pattern as the first trace line TSL1, fine scratches and/or short-circuit defects in the first trace line TSL1 that may be otherwise difficult to inspect can be easily inspected.

The second insulating layer IL2 is disposed on the first insulating layer IL1 and first inspection lines CDL1.

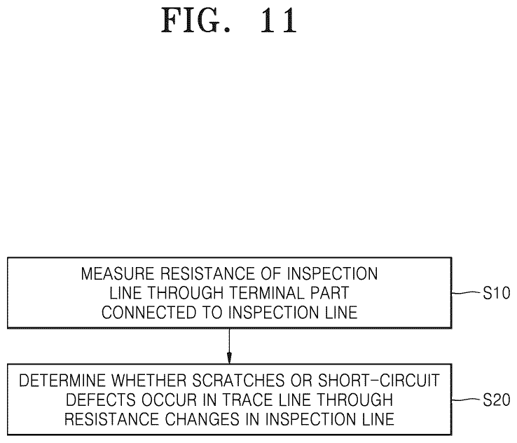

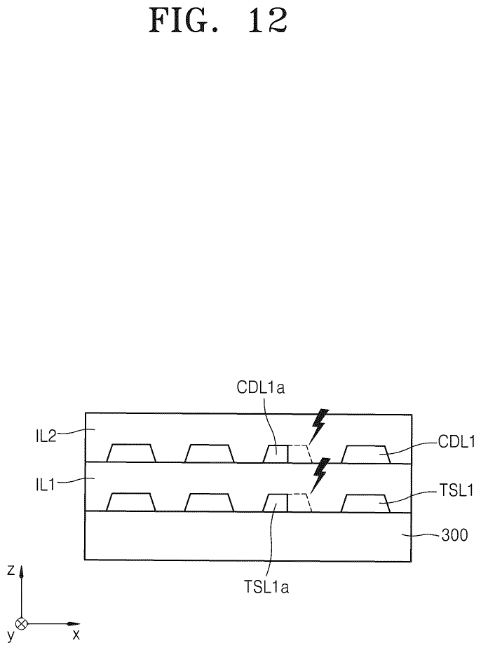

FIG. 11 is a flowchart of a method of inspecting defects in a display apparatus, according to an embodiment, and FIG. 12 is a cross-sectional view that illustrates a method of inspecting defects in a display apparatus, according to an embodiment.

Referring to FIG. 11, a method of detecting defects in a display apparatus according to an embodiment includes determining whether the trace line TSL is defective using the inspection line CDL. Determining whether the trace line TSL is defective using the inspection line CDL includes measuring resistance of the inspection line CDL through the terminal part PAD connected to the inspection line CDL (S10), and determining whether scratch defects or short-circuit defects occur in the trace line TSL through resistance changes in the inspection line CDL.

Referring to FIGS. 11 and 12, in an embodiment, whether the display apparatus is defective can be determined using a display apparatus formed by processes of FIGS. 10A to 10F. For example, whether the trace line TSL is defective can be determined using the inspection line CDL in the display apparatus. FIG. 12 shows an example of the trace line TSL and the inspection line CDL, and shows, for convenience of illustration, a method of inspecting defects in the first trace line TSL1 using the first inspection line CDL1.

Referring to FIGS. 11 and 12, the first inspection line CDL1 includes a conductive oxide. The first inspection line CDL1 is connected to the terminal part PAD. Accordingly, a resistance of the first inspection line CDL1 can be measured through the terminal part PAD or the printed circuit board connected to the terminal part PAD (S10).

The first inspection lines CDL1 overlap the first trace line TSL1. When fine scratches or short-circuit defects occur in some of the first inspection lines CDL1 due to factors in a manufacturing process, fine scratches or short-circuit defects typically occur also in the first trace line TSL1 disposed under the corresponding first inspection line CDL1 in which the defects occur. For example, when scratch defects occur in a third first inspection line CDL1 shown in FIG. 12, scratch defects occur also in a third first trace line TSL1a disposed thereunder.

Accordingly, whether fine scratches or short-circuit defects occur in the first trace line TSL1 can be determined by measuring resistance changes in the first inspection line CDL1. In an embodiment, the first inspection lines CDL1 are respectively connected to other terminals in the terminal part PAD. Whether fine scratches occur in the third first trace lines CDL1a can be determined by measuring resistance changes in the third first inspection line CDL1a. In an embodiment, the first inspection lines CDL1 are connected to each other using one line and connected to one terminal in the terminal part PAD. For example, whether fine scratches or short-circuit defects occur in some of the first trace lines TSL1 is determined by measuring resistance changes in the first inspection lines CDL1.

According to embodiments, a display apparatus that enables defect inspection and detection of a trace line, a method of manufacturing a display apparatus, and the method of inspecting the defects are provided. However, the scope of embodiments of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus, comprising:
a substrate that includes a display area and a peripheral area outside the display area;
a sealing substrate disposed on the substrate;
a touch sensor layer disposed on the sealing substrate;
a trace line disposed on the sealing substrate in the peripheral area; and
an inspection line disposed on the trace line and that overlaps the trace line,
wherein the inspection line includes a different material from the trace line.

2. The display apparatus of claim 1, wherein the touch sensor layer includes driving electrodes and sensing electrodes, and the trace line is connected to at least some of the driving electrodes and some of the sensing electrodes.

3. The display apparatus of claim 1, wherein the inspection line includes a conductive oxide.

4. The display apparatus of claim 1, wherein each of the trace line and the inspection line includes a plurality of trace lines and a plurality of inspection lines, respectively, and a number of inspection lines is equal to a number of trace lines.

5. The display apparatus of claim 1, wherein the inspection line completely overlaps the trace line.

6. The display apparatus of claim 5, wherein the trace line is insulated from the inspection line.

7. The display apparatus of claim 6, wherein an insulating layer is interposed between the trace line and the inspection line.

8. The display apparatus of claim 1, wherein the inspection line is connected to a terminal part in the peripheral area.

9. A method of manufacturing a display apparatus, the method comprising:
forming a substrate that includes a display area and a peripheral area;
forming a sealing substrate on the substrate;
forming a touch sensor layer on the sealing substrate;
forming a trace line on the sealing substrate in the peripheral area; and
forming an inspection line on the trace line such that the inspection line overlaps the trace line,
wherein the inspection line includes a different material from a material of the trace line.

10. The method of claim 9, wherein forming the inspection line includes:
forming an insulating layer on the trace line; and
forming the inspection line on the insulating layer.

11. The method of claim 9, wherein forming the trace line includes:
forming a first conductive layer;
forming, on the first conductive layer, a first photoresist pattern using a first mask; and
etching the first conductive layer using the first photoresist pattern as a mask.

12. The method of claim 11, wherein forming the inspection line includes:
forming a second conductive layer;
forming, on the second conductive layer, a second photoresist pattern using a second mask; and
etching the second conductive layer using the second photoresist pattern as a mask.

13. The method of claim 12, wherein the second mask is a same as the first mask.

14. The method of claim 9, wherein the inspection line includes a conductive oxide.

15. The method of claim 9, wherein each of the trace line and the inspection line includes a plurality of trace lines and a plurality of inspection lines, respectively, and a number of inspection lines is equal to a number of trace lines.

16. The method of claim 9, wherein forming the touch sensor layer includes forming driving electrodes and sensing electrodes, and
wherein the trace line is connected to at least some of the driving electrodes and some of the sensing electrodes.

17. The method of claim 9, wherein the inspection line is connected to a terminal part in the peripheral area.

18. A method of detecting defects in a display apparatus that includes a touch sensor layer, including: determining whether a trace line of the touch sensor layer disposed on a sealing substrate of display apparatus in a peripheral area is defective using an inspection line disposed on the trace line and that overlaps the trace line.

19. The method of claim 18, wherein determining whether the trace line is defective includes:
measuring a resistance of the inspection line through a terminal part connected to the inspection line; and
determining whether the trace line has scratches or short-circuit defects through resistance changes in the inspection line.

20. The method of claim 18, wherein the inspection line includes a conductive oxide.
